(19) United States
(12) Patent Application Publication
(10) Pub. No.: US 2014/0190401 A1
(43) Pub. Date: Jul. 10, 2014

(54) METHOD, SYSTEM, AND APPARATUS FOR DOPING AND FOR MULTI-CHAMBER HIGH-THROUGHPUT SOLID-PHASE EPITAXY DEPOSITION PROCESS

(71) Applicant: Fareed SEPEHRY-FARD, Saratoga, CA (US)

(72) Inventor: Fareed SEPEHRY-FARD, Saratoga, CA (US)

(21) Appl. No.: 14/150,629

(22) Filed: Jan. 8, 2014

Related U.S. Application Data
(62) Division of application No. 11/740,286, filed on Apr. 25, 2007, now abandoned.

(51) Int. Cl. C30B 23/02

(52) U.S. Cl. CPC C30B 23/02
USPC 117/105

(57) ABSTRACT

A doping and multi-chamber method and apparatus for the growth of material, directed toward Solid Phase Epitaxy (SPE) process, is disclosed. Different variations and features of this method and process are examined. The advantages of this method are the high throughput and the reduced operational cost of the production for semiconductor material and devices, such as III-V material (e.g. GaAs) and solar cell devices. It can be applied to many systems and devices/materials.

### RELATED APPLICATIONS

This application is a division of U.S. patent application Ser. No. 11/740,286 (Attorney Docket No. AHURA-002), filed Apr. 25, 2007, pending, which is incorporated herein by reference in its entirety. The current application may also be related to U.S. patent application Ser. No. 11/559,893, filed Nov. 14, 2006, with the same inventor and assignee, which teaches very high efficiency multi junction solar spectrum integrator cells, and the corresponding system and method, including a Solid Phase Epitaxy (SPE) method and process.

### DISCUSSION OF THE BACKGROUND

The current application may be related to U.S. Pat. No. 5,725,659, issued Mar. 10, 1998 to Sepehry-Fard (issued to the current inventor and assignee), which teaches a Solid-Phase Epitaxy (SPE) reactor, the most cost effective GaAs epitaxial growth technology, and discloses an apparatus for performing SPE deposition, for growing layers of semiconductive material, that includes a reaction chamber and means for mounting a substrate wafer and a source wafer in the reaction chamber. The substrate wafer and the source wafer are maintained at a predetermined distance, which is less than the mean free path of the reactive species of the oxido-reduction of the semiconductive material. A heater for heating the wafers maintains a temperature difference of 20-40° C. between the wafers.

The teachings of the above (the related patent and application) are incorporated herein by reference, and thus, are not repeated here.

The following references may also be of some relevance.

Son et al., U.S. Pat. No. 7,141,116, issued Nov. 28, 2006, teaches a method for manufacturing a silicon structure. The improved methods for forming silicon films, particularly single-crystal silicon films, from amorphous silicon films, in which a single-crystal silicon substrate is prepared by removing any native oxide, typically using an aqueous HF solution, and placed in a reaction chamber. The substrate is then heated from about 350° C. to a first deposition temperature, under a first ambient to induce single-crystal epitaxial silicon deposition, primarily on exposed silicon surfaces. The substrate is then heated to a second deposition temperature under a second ambient, that will maintain the single-crystal epitaxial silicon deposition on exposed single-crystal silicon, while inducing amorphous epitaxial silicon deposition on insulating surfaces. The amorphous epitaxial silicon can then be converted to single-crystal silicon using a solid phase epitaxy process to form a thin, high quality silicon layer. The first and second ambients include at least one silicon source gas and may include a non-oxidizing carrier gas.

Krishnan teaches a tip architecture with SPE for buffer and deep source/drain regions, U.S. Pat. No. 7,045,433, issued May 16, 2006: A method of manufacturing a semiconductor device includes forming a gate, source/drain extensions, buffer regions, and source/drain regions. The gate is formed over a semiconductor layer, and the source/drain extensions are formed within the semiconductor layer and adjacent to the gate. The buffer regions are formed within first amorphous implant regions, and the source/drain regions are formed within second amorphous implant regions. The buffer regions and the source/drain regions are activated using solid-phase epitaxy, whereby sidewalls of the activated buffer regions and the activated source/drain regions are substantially vertical.

Meier et al. teaches a method and apparatus for self-doping contacts to a semiconductor, U.S. Pat. No. 6,703,295, issued Mar. 9, 2004: A system and method for creating self-doping contacts to silicon devices, in which the contact metal is coated with a layer of dopant and subjected to high temperature, thereby alloying the silver with the silicon, and simultaneously doping the silicon substrate and forming a low-resistance ohmic contact to it. A self-doping negative contact may be formed from unalloyed silver which may be applied to the silicon substrate by either sputtering, screen printing a paste, or evaporation. The silver is coated with a layer of dopant. Once applied, the silver, substrate and dopant are heated to a temperature above the Ag--Si eutectic temperature (but below the melting point of silicon). The silver liquefies more than a eutectic proportion of the silicon substrate. The temperature is then decreased towards the eutectic temperature. As the temperature is decreased, the molten silicon reforms through liquid-phase epitaxy, and while doing so, dopant atoms are incorporated into the regrown silicon lattice. Once the temperature drops below the silver-silicon eutectic temperature, the silicon which has not already been reincorporated into the substrate through epitaxial re-growth forms a solid-phase alloy with the silver. This alloy of silver and silicon is the final contact material, and is composed of eutectic proportions of silicon and silver. Under eutectic proportions, there is significantly more silver than silicon in the final contact material, thereby insuring good electrical conductivity of the final contact material.

Armitage, Jr. et al. teaches a fabrication of photovoltaic devices by solid phase epitaxy, U.S. Pat. No. 4,165,558, issued Aug. 28, 1979: Devices produced by this method consisting of a semiconductor base and a semiconductor junction-forming epitaxial layer. The epitaxial layer is grown by solid phase means from a metal-semiconductor alloy or from a sandwich structure of semiconductor/metal on the semiconductor base.

As can be seen, the current application is very different from the methods mentioned in the prior art, including the ones mentioned above.

This “Discussion of the Background” section is provided for background information only. The statements in this “Discussion of the Background” are not an admission that the subject matter disclosed in this “Discussion of the Background” section constitutes prior art to the present disclosure, and no part of this “Discussion of the Background” section may be used as an admission that any part of this application, including this “Discussion of the Background” section, constitutes prior art to the present disclosure.

### SUMMARY OF THE INVENTION

The current application deals with the doping and multi-chamber method and apparatus for the growth of material, directed toward SPE process. We will examine different variations and features of this invention. The advantages of the current invention are the speed of production and reduction in the cost of production, for the material and the devices.

### BRIEF DESCRIPTION OF THE DRAWINGS

FIG. 1 shows a typical SPE system, comprising: (1) CO₂, O₂, N₂, and H₂ gas cylinders, (2) valves, (3) flux meters, (4) water saturator, (5) thermocouples, (6) basket for external doping sources, (7) fused silica sample holder, (8) graphite blocks, (9) fused silica spacers and GaAs source and substrate, (10) 1000 W tungsten halogen lamp, (11) 2000 W tungsten halogen lamp, (12) thermometer, (13) controller for the source temperature, (14) controller for the substrate temperature, (15) trap, (16) glycerol bubbler, and (17) burner.

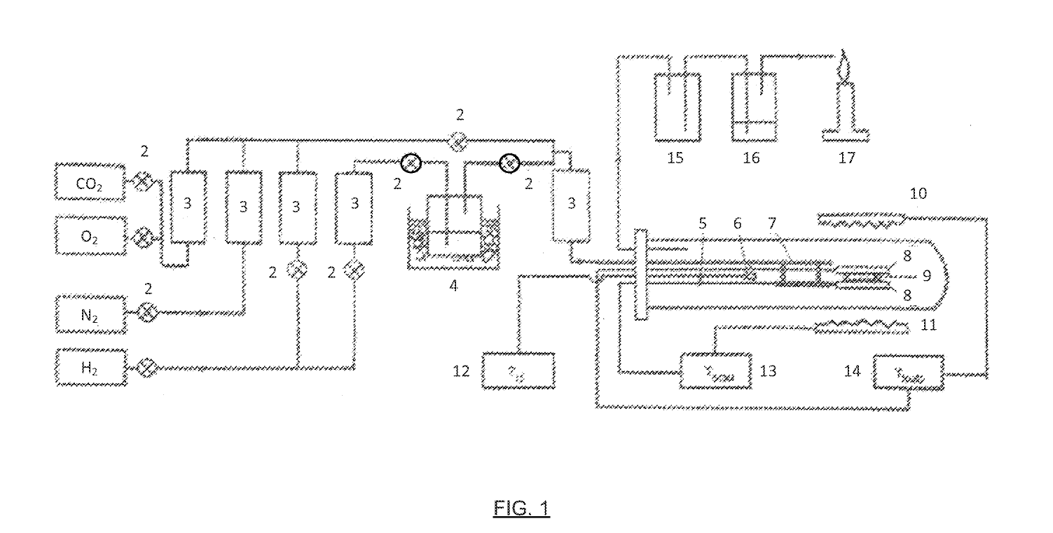

FIG. 2 shows a growth rate of GaAs epitaxial layers grown in an H₂+H₂O ambient as a function of the water vapor pressure, PH₂O.

FIG. 3 shows the growth rate of GaAs epitaxial layers grown in H₂+CO₂ ambient as a function of the pressure, PCO₂.

FIG. 4 shows a charge density of GaAs epitaxial layers grown in H₂+H₂O ambient as a function of the water vapor pressure, PH₂O, in which a Zn doped GaAs wafer characterized by Nnet≈3×10¹⁹ cm⁻³ was used as source, and the full line represents the maximum doping concentration of Zn, n Zn, max calculated with the diffusion controlled model (right y axis).

FIG. 5 shows a charge density of GaAs epitaxial layers grown in H₂+CO₂ ambient as a function of the pressure, PCO₂, in which a Zn doped GaAs wafer characterized by Nnet≈3×10¹⁹ cm⁻³ was used as the source.

FIG. 6 shows charge density profiles of GaAs epilayers grown in different doping environments, in which all growth conditions for the layers were kept constant other than as follows: A: in presence of external doping source of Zn, in which the temperature of Zn is 550° C. and is placed 3.4 cm from the graphite blocks; B: in the reactor contaminated by the previous deposition; C: in the reactor followed by a normal cleaning procedure.

FIG. 7 shows a hole concentration in GaAs epilayers doped with an external Zn source as a function of the temperature of Zn source.

FIG. 8 shows a free electron concentration of GaAs epilayers doped with the external source of Ge as a function of the temperature of the Ge source.

FIG. 9 shows morphological aspects of GaAs layers grown under various water vapor pressures, PH₂O, and water injection temperatures, Tinj, in the reactor.

FIG. 10 shows an embodiment of a setup for multiple source and/or substrate growth.

FIG. 11 shows an embodiment of a setup for multiple source and/or substrate growth, which can be both arrangements for source and/or substrate, rotating in any direction; rotating individually or as a group, laterally, horizontally, or vertically; moving, rotating, or stopping at different times; as a time-truncated event; based on coordinates, positions, x, y, z, and time, the whole operation of which can be managed by computer control.

FIG. 12 shows an embodiment of the arrangement for the source and/or substrate and growth, which can be for the source and the substrate, showing thermocouple and other controls for adjusting partial pressures and other growth parameters.

FIG. 13 shows an embodiment of the arrangement for the substrate and growth, which can be for the source and/or the substrate.

### DETAILED DESCRIPTION

Reference will now be made in detail to various embodiments of the invention, examples of which are illustrated in the accompanying drawings. While the invention will be described in conjunction with the following embodiments, it will be understood that the descriptions are not intended to limit the invention to these embodiments. On the contrary, the invention is intended to cover alternatives, modifications and equivalents that may be included within the spirit and scope of the invention as defined by the appended claims. Furthermore, in the following detailed description, numerous specific details are set forth in order to provide a thorough understanding of the present invention. However, it will be readily apparent to one skilled in the art that the present invention may be practiced without these specific details. In other instances, well-known methods, procedures, components, and circuits have not been described in detail so as not to unnecessarily obscure aspects of the present invention.

Despite the many advantages that SPE has, so far, multilayer growth has been difficult in one growth run, because, for example, the GaAs source cannot be changed during the epitaxial growth. The type of layer and its charge density are determined when the source is chosen (since (e.g.) GaAs and all dopants come from the GaAs wafer used as the source). Significant change in the doping level of n-type GaAs epilayers and the change from n to p type can only be obtained by selecting different GaAs sources. The transport agent does not influence the doping level of the epitaxial layers. Other transport agents besides water vapor can both serve as the transport agent and a doping source. Adding some properly selected dopants into the reactor may also be a good alternative for the dopants being incorporated into the layer during the growth.

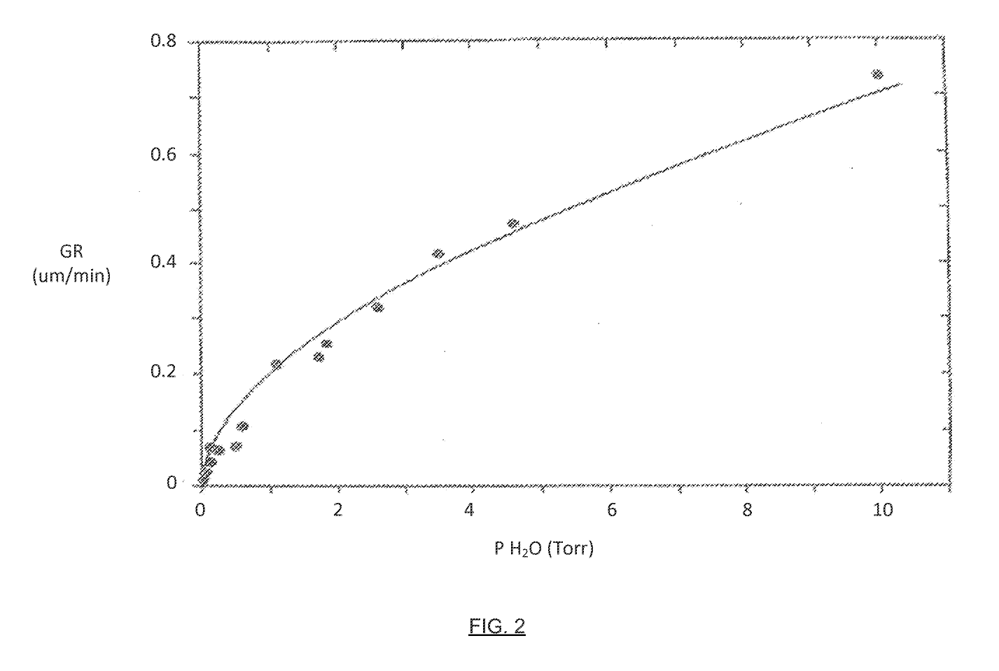

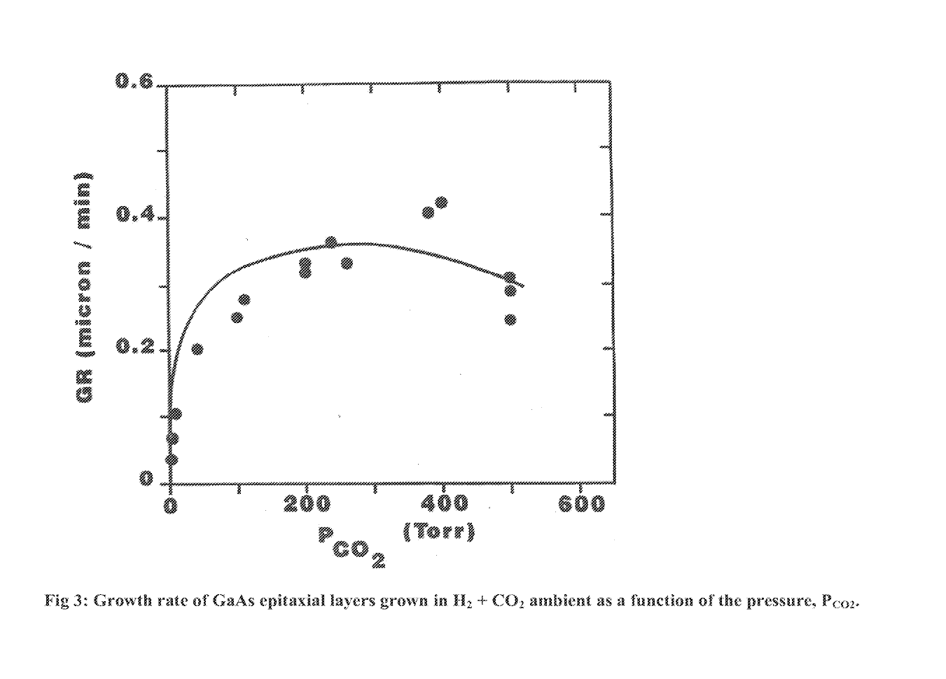

One method is the GaAs growth in H₂+CO₂, rather than H₂+H₂O. FIGS. 2 and 3 show the variation of the growth rate measured as a function of PH₂O and PCO₂, respectively. Full lines represent calculated growth rates.

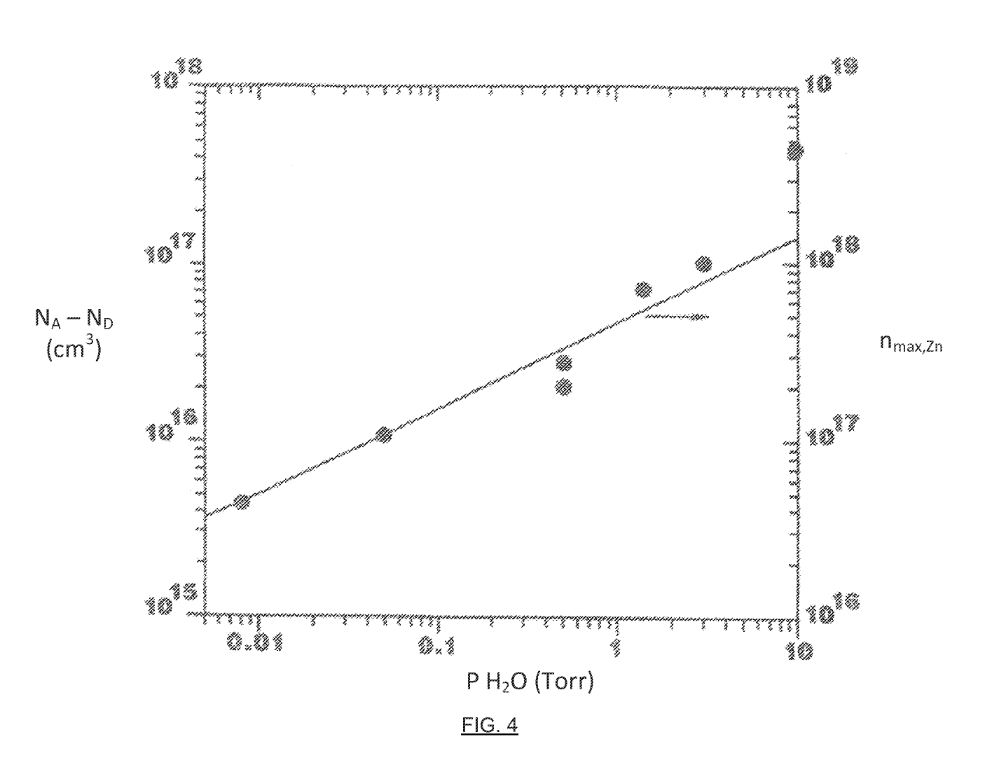

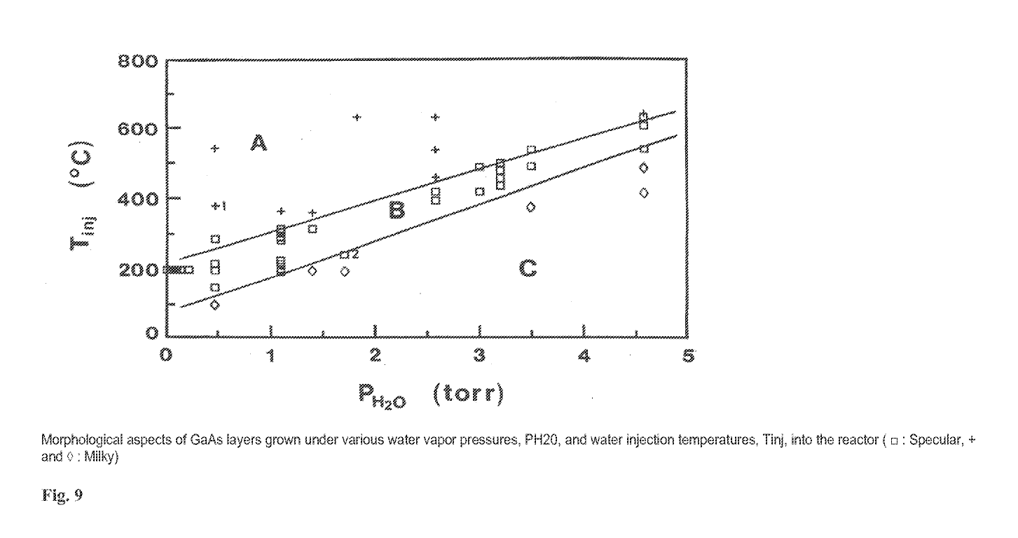

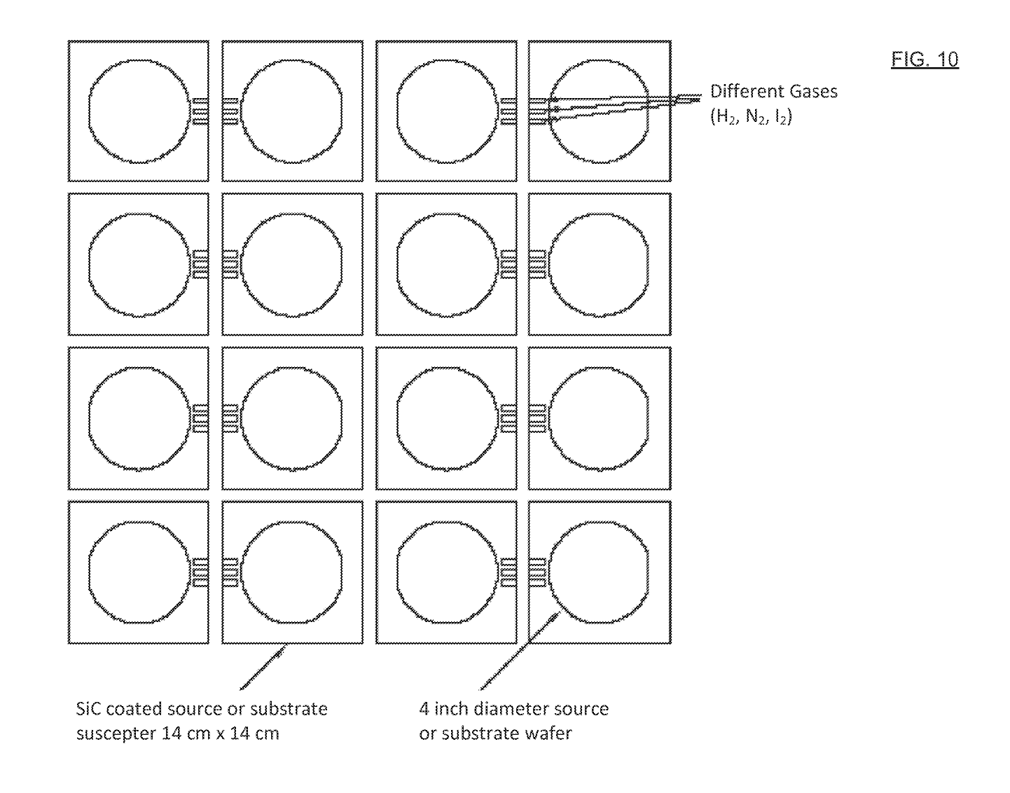

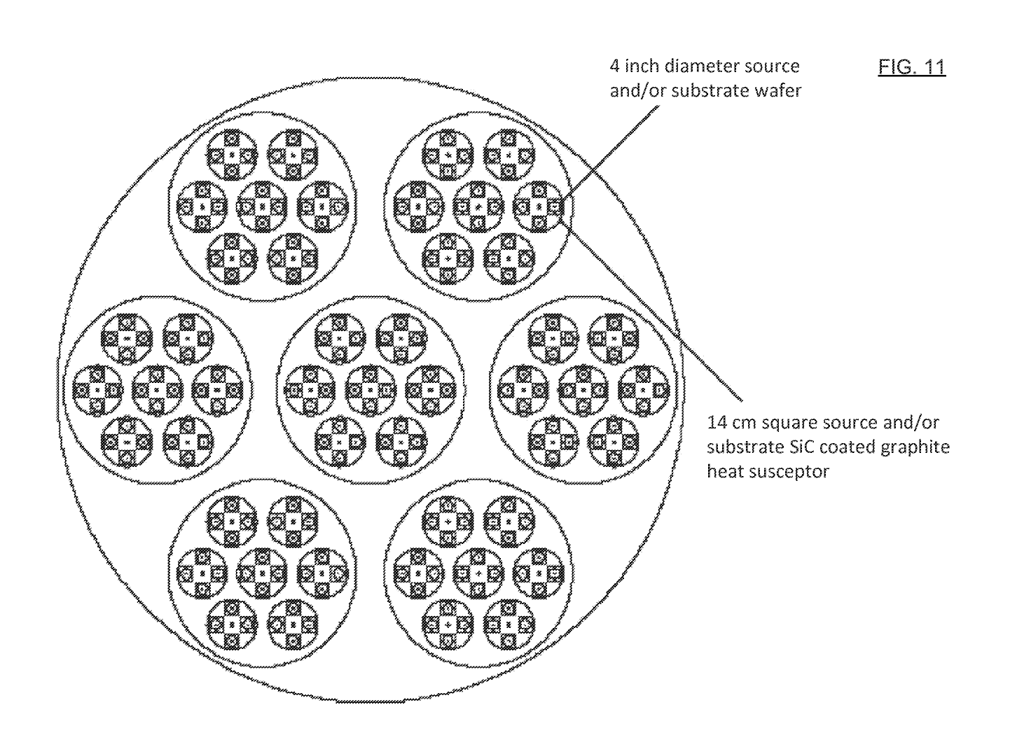

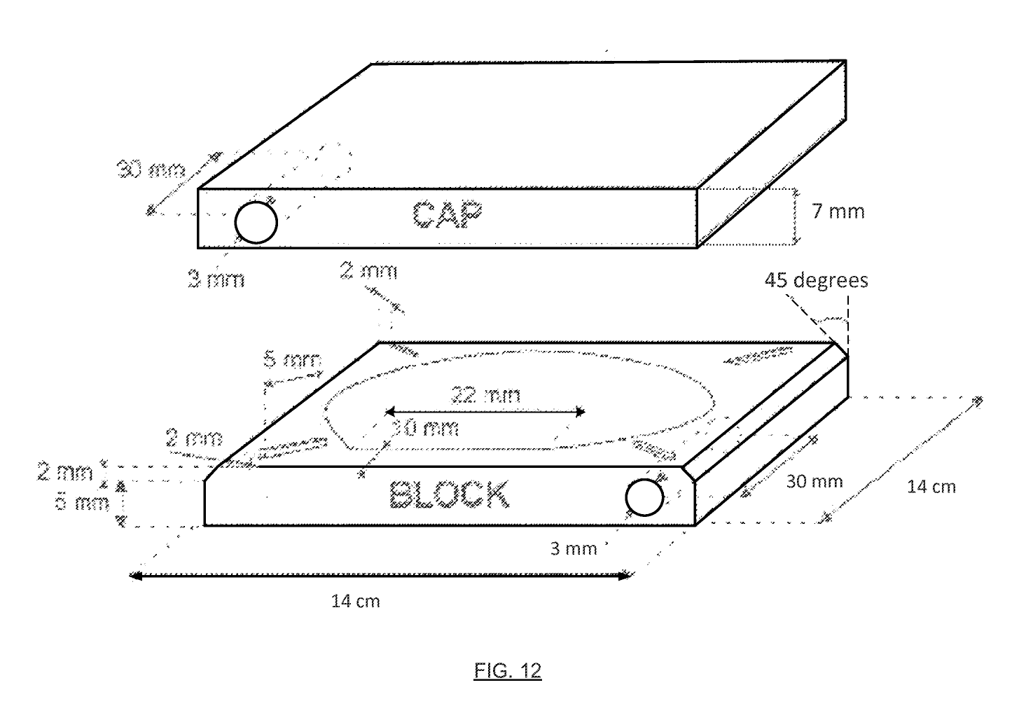

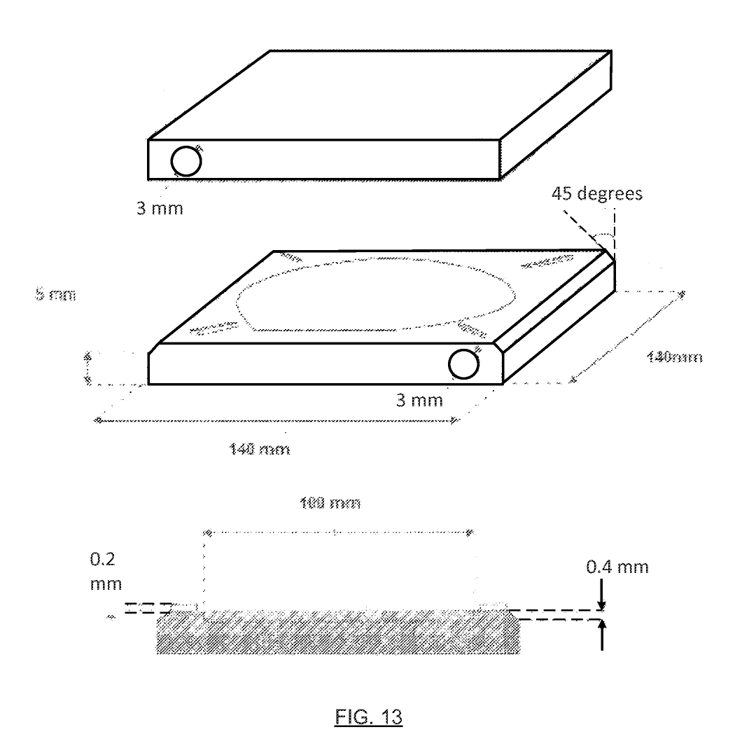

FIGS. 4-8 represent the trend for doping, activation, and impurity concentration. FIG. 9 represents the range for good morphological growth. FIGS. 10-11 show multiple-source and/or substrate utilization/growth. FIGS. 12-13 represent the growth and source and substrate setting/parameters.

We have experienced that (i) PCO₂ is much higher than PH₂O for equivalent growth rates; (ii) a maximum growth rate occurs in H₂+CO₂ ambient for PCO₂ of about 300-400 torr; an equivalent behavior does not exist in H₂+H₂O ambient for which the growth rate rises as PH₂O is increased.

When the growth of GaAs is performed in H₂+H₂O ambient, the reactions involved in the transport are provided using H₂O. Since the transport of GaAs also takes place in H₂+CO₂ ambient, it was suspected that the following reactions could also occur in the reactor (Eqs. 1 and 2 given below):

CO₂(g)+H₂ [symbol] CO(g)+H₂O(g) (1)

CO₂(g)+2H₂(g) [symbol] (s)+2H₂O(g) (2)

These reactions would provide in-situ the water necessary for the transport of GaAs. The 200° C., 15 min baking step of the reactor before deposition prevents the participation in the transport reaction of adventitious water adsorbed on the reactor hardware when it is open to ambient air for loading the source and substrate. This has been verified by running an experiment in which the graphite holders were brought to the growth temperatures Tl and T2 and held there for 15 min without injecting water. Then, they were cooled down. No GaAs deposition was observed for that run.

The presence of CO and H₂O from reactions 1 and 2 was checked by analyzing the reactor exhaust gases. Besides CO₂, there are other peaks in the gas chromatogram. They are attributable to H₂O and CO. The reaction times and relative concentrations for H₂O, CO and CO₂ present in the reactor exhaust gases are given in Table 1. From these results, it appears that both reactions 1 and 2 provide water in-situ. However, the contribution of reaction 1 is minor, in the experimental growth conditions.

TABLE I
Retention times, and relative concentrations for H₂O, CO, and CO₂
present in the reactor exhaust gases, and for external standards.
(Note for caption: a. Deduced from peak heights; b. PCO₂ = 100 Torr.)

| | | Relative | |
|---|---|---|---|
| | | Concentration^{a} | Relative Concentration^{a} |
| | | (ppm) | (ppm) |
| Gas | Reaction Time (min) | Standard | Sample |
| H₂O | 0.85 | 1315 | 1070 |
| CO | 0.89 | 1000 | 30 |
| CO₂ | 1.60 | — | Major Gas^{b} |

The total amount of water generated in situ by both reactions in H₂+CO₂ ambient, when PCO₂=100 torr, is 1070 ppm. It is equivalent to PH₂O=0.84 torr. For that water vapor pressure, GR=0.18 μm min⁻¹ in H₂+H₂O ambient (FIG. 2) (while GR=0.25 μm min⁻¹ in H₂+CO₂ ambient with PCO₂=100 to44). If one takes into account the possible accumulation of all error sources (growth rates in both ambients, detection and calibration of H₂O in the exhaust gases, and equivalence of the water concentration in the reactor and in the exhaust gases in H₂+CO₂ ambient), the growth rates in both ambients are nevertheless in good agreement.

Electrical Properties of GaAs Layers:

a. Variation with the Growth Ambients:

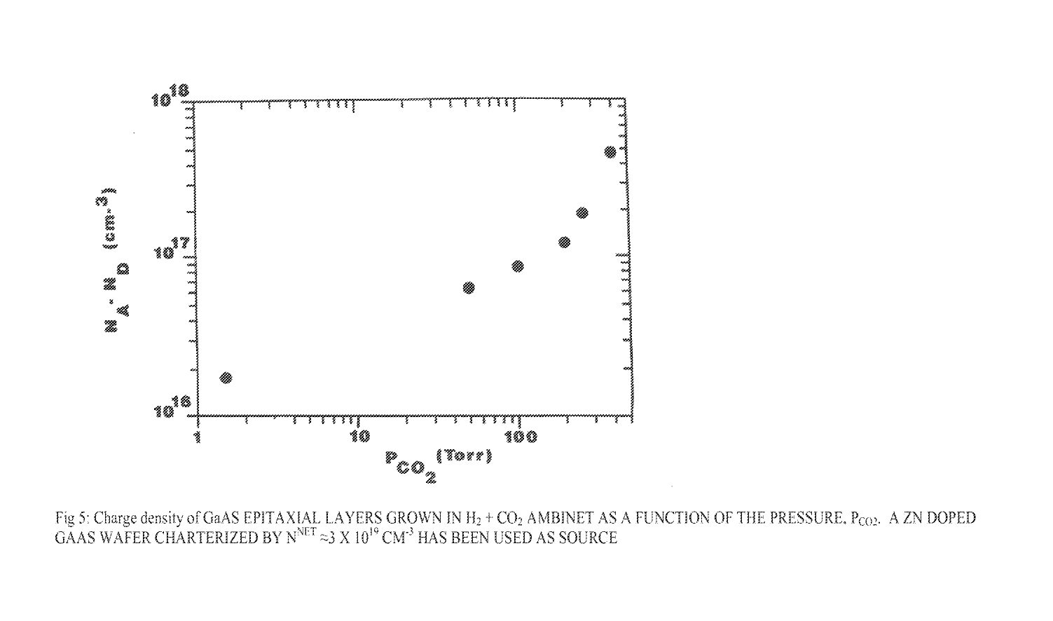

The dark circles in FIGS. 4 and 5 show the variation of the p-type carrier density (NA-ND) measured as a function of PH₂O and PCO₂, respectively. All these results were obtained by growing GaAs layers from a heavily doped (NA-ND=2.9×10¹⁹ cm⁻³) Zn—GaAs source on a heavily doped (100) Zn—GaAs substrate. The other growth conditions were identical to the ones reported in the previous section. The full line in FIG. 4 represents the calculated maximum doping levels according to a theoretical model.

It is important to notice that (i) all layers are p-type with a charge density increasing with the increase of PH₂O or PCO₂; and (ii) the range of NA-ND is nearly the same in both FIGS. 4 and 5. It means that C is not incorporated in the growing layers as a major electrically active p-type impurity, when GaAs films are grown in H₂+CO₂ ambient, despite the fact that reaction (2) is the major reaction for in situ water generation. The highest transport coefficient measured for Zn in this work is found at the highest PH₂O or PCO₂ used. It is about 1.5% for both ambients at the normal growth temperatures.

b. Variation with the Growth Temperatures:

There is only one aspect of the transport of Zn as a doping impurity which is different for both ambients: it is the behavior of NA-ND with the substrate temperature. The figure shows (dark symbols) the charge density profile of a layer of GaAs grown in H₂+CO₂ ambient (PCO₂=200 torr) at three successive temperatures: Tsub=850° C. for 5 min, 800° C. for 10 min, and 760° C. for 15 min, with Tsou=Tsub+40° C. (indicating the temperatures for the source and substrate, respectively). Both source and substrate are Zn doped (100) GaAs with NA-ND=2.9×10¹⁹ cm⁻³. Three plateaus are clearly visible in the NA-ND profile. They are NA-ND=2.2×10¹⁷, 3.4×10¹⁷, and 5.3×10¹⁷, for Tsub=760, 800, and 850° C., respectively.

When the same experiment is performed in H₂+H₂O ambient (open symbols) there is no variation of NA-ND with the substrate temperature. The same behavior was already observed when Ge or Te doped n-type GaAs wafers were used as sources in H₂+H₂O ambients.

c. Comments on Variation of Growth Ambients:

It is possible to grow GaAs layers in H₂+CO₂ ambient. The transport gas is H₂O, which is generated in situ, mainly by reaction of H₂ with CO₂, yielding, at the growth temperature, water vapor and carbon. Unfortunately the latter is unable to be incorporated as a major p-type.

For doping impurity in the growing layer: As far as the carrier density is concerned, there are only minor differences between layers grown in H₂+H₂O or H₂+CO₂ ambients.

However, H₂+CO₂ ambient may be very useful to grow very thin epitaxial layers, which is difficult to obtain in H₂+H₂O ambient, due to difficulties of getting very low water vapor pressures. The reason is simple: PCO₂ must be about two orders of magnitude higher than PH₂O to obtain GaAs layer of comparable thickness. It is therefore easier to control PCO₂ down to very low pressure. Another use of H₂+CO₂ may be in heteroepitaxy of GaAs on Ge. In H₂+CO₂ ambient, the pretreated Ge surface is oxidized before the GaAs layers start to grow on it. This makes epilayers on Ge milky. This problem has been solved by high temperature inversion, to remove the oxidized layer form Ge before the deposition. Since water is produced at the growth temperature, H₂+CO₂ ambient may be used to grow heteroepitaxy without high temperature inversion, which is a time consuming step.

External Doping by Adding Pure Elements (Zn, Ge, Te):

Various elements can be used as either n- or p-type dopants for GaAs. So far, we have tried to dope GaAs epilayers with Ge, Zn, brass (an alloy of Cu and Zn), Au, Sn, Te and Cu. It was found that Ge, Te and Zn are the elements that can successfully dope the GaAs in SPE under the normal growth conditions, mentioned previously. Even more important is that the doping levels can easily be controlled through the temperature of the external doping source, which is independent of the temperature of the GaAs source. However, other elements tried here, or otherwise, are still good candidates for doping, but may need more calibrations for optimum parameter settings for best activation or reasonable control of activation.

In this section, we will describe how GaAs is externally doped and also report the electrical properties of the epitaxial layers.

An epilayer grown from SI-GaAs sources in a clean, uncontaminated reactor is n-type with a carrier density of about 2×10¹⁶/cm⁻³. This is used as a reference for the cleanliness of the reactor. If the reactor can produce the same carrier density as the reference, then we say that the reactor is clean. The doping experiments always start by checking the background doping to see if the reactor is contaminated. During this first step, an epilayer is grown in a clean reactor, its carrier density and the type of layer are determined and compared with the reference. Then, as a known step, an epilayer is grown with an external doping source at the doping position in the reactor. This is obtained by approaching the doping source toward the graphite susceptors. The type of layer and its carrier density are determined. Finally, the doping source being withdrawn to a lower temperature region of the reactor, an epilayer is grown in the dopant contaminated reactor to determine the degree of contamination, caused by the previous deposition. The dopant contamination of the reactor is eliminated by cleaning all the fused silica parts of the reactor in an aqueous solution of 3% HF, followed by rinsing with NaOH 0.1M, HCl 3%, and de-ionized water. Then, the decontamination of the graphite blocks is conducted by reacting them at 850° C. during 30 min in H₂+H₂O (4.6 torr) ambient. In the case of a severely contaminated reactor, this cleaning procedure may have to be repeated more than once.

P-type external doping by Zn:

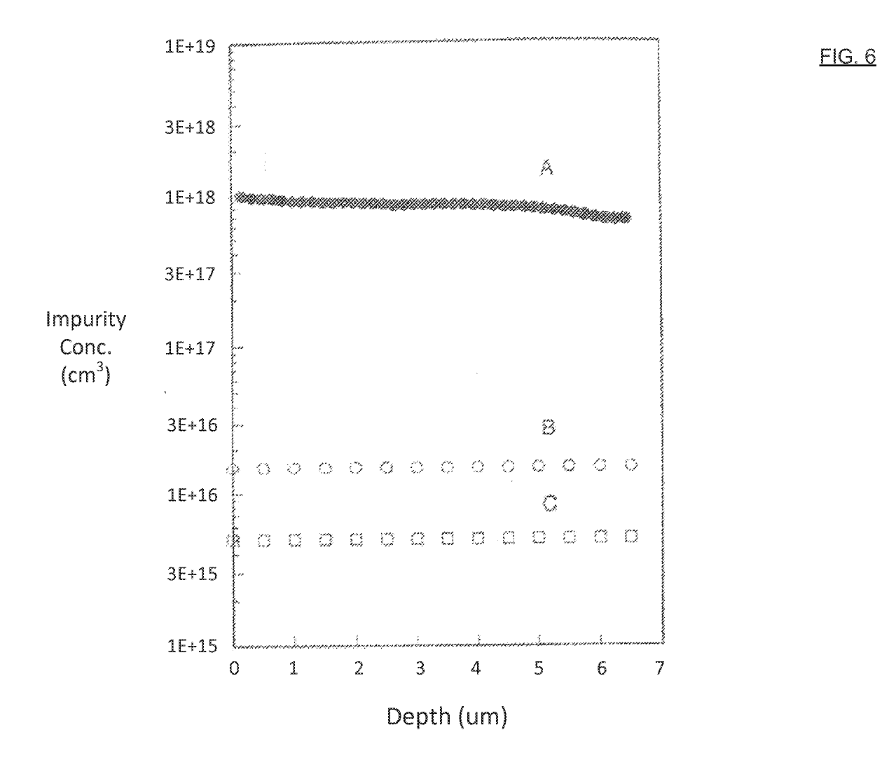

FIG. 6l shows a typical cycle for doping experiments with a Zn external doping source of Zn. Line A (filled circles) shows the measured carrier density profile of the p-type epilayer doped, with Zn maintained at 550° C. during the growth of GaAs. The slightly low charge density near the interface between the epitaxial layer and the substrate (right side of the graph) is most probably caused by a lower external source temperature at the beginning of the growth. It has indeed been observed that most of the temperature increase of the external doping source happened during the first 5 min, for a 15 min epitaxial growth period, before a more stable temperature was reached. In that 5 min period, the change of temperature amounted 70% of temperature increase of 50 to 60° C. of the external doping sources during the growth. If the external source is closer to the graphite blocks, the time spent to reach a stable temperature is shorter. Again, this can be easily corrected by independently heating the source, or pulling the external source away from the graphite susceptors.

Line B (open circles) displays a check on the contamination of the reactor after the doping step. The layer is p-type with a charge density in the low 10¹⁶ cm⁻³ range. Line C (squares) is the background doping of a layer grown in the reactor, cleaned only once. It is n-type with a charge density between 10¹⁵ and 10¹⁶ cm⁻³. These results clearly indicate that Zn does dope the GaAs epitaxial layer in this way. The Zn contamination left from the previous deposition is very small.

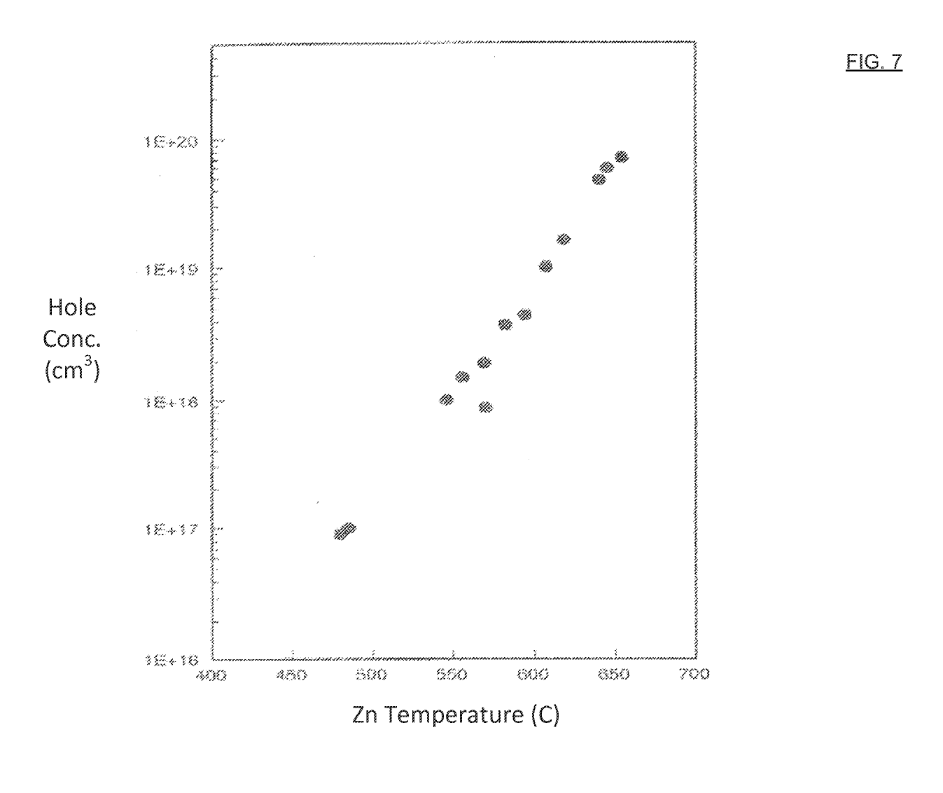

FIG. 7 shows the variation of carrier density of epitaxial layers with the temperature of the external doping source, Zn. Each point in the figure stands for one cycle of experiments, mentioned above. In every cycle, the layers obtained by checking background doping are n-type, with a carrier density of 5×10¹⁵ to 2×10¹⁶. In most cases, the charge density is lower than that of the reference, 2×10¹⁶, resulting from slight Zn compensation. This can be corrected by repeating the cleaning procedure. Zn contamination of the reactor resulting from Zn external doping is at least one order of magnitude lower than the external doping level reached in the previous deposition. The introduction of an external doping source of Zn has no influence on the morphology and the growth rate of the epilayers. However, the growth rate is significantly reduced when the Zn temperature reaches 650° C. This may be caused by the fact that too much Zn oxide impairs the normal GaAs growth.

It has been demonstrated that elemental Zn does dope the epitaxial layers and that doping levels ranging from 5×10¹⁶ to 5×10¹⁹ cm⁻³ can be controlled by adjusting the temperature of Zn. When water vapor is used as transport agent, the reactions involved in SPE to grow the bulk GaAs epilayers are those given before. The following two reactions may be envisaged for the transfer of Zn which is used as p-type dopant:

Zn(s) [symbol] Zn(g) (3)

Zn(s)+H₂O(g) [symbol] ZnO(g)+H₂(g) (4)

Contrary to the case of the use of a Zn doped GaAs source, we cannot calculate or even estimate here the maximum doping concentrations from the diffusion-controlled model, because the reduced spacing in SPE condition is not valid for elemental Zn, and a very small portion of Zn was actually incorporated into the epilayer, while most of it was lost to the wall of the reactor (which results in a darkened reactor). However, it has already been demonstrated, by using Zn doped GaAs sources, that reaction (4) is responsible for the transport of Zn in SPE.

N-Type External Doping by Ge and Te:

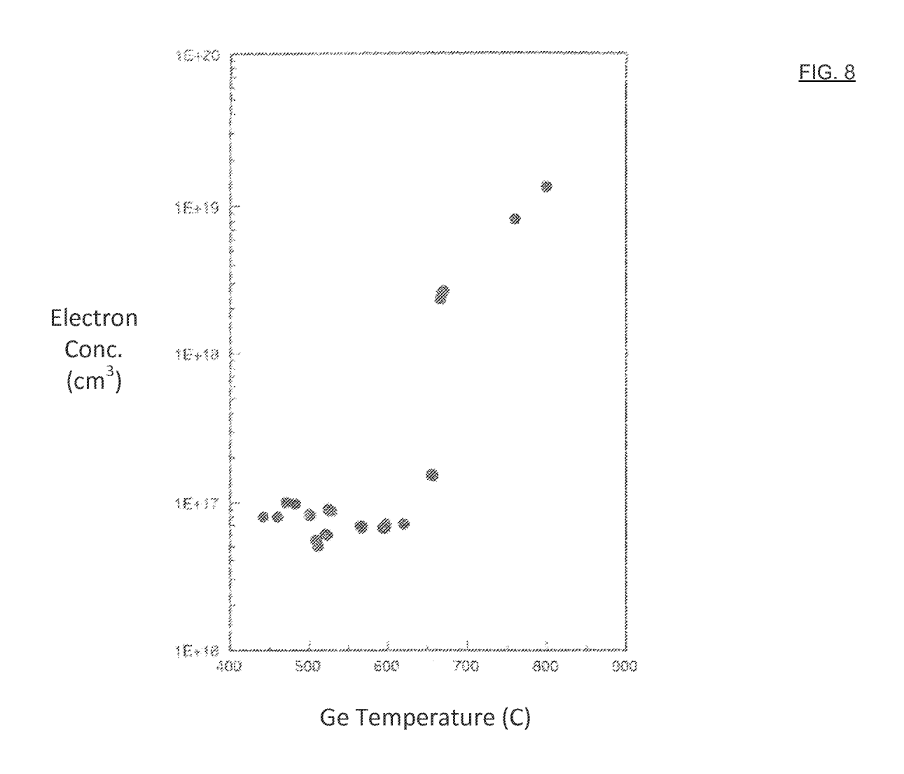

The same procedure of external doping has been followed to grow n-type epilayers, but, in this case, Ge or Te external doping sources were used. FIG. 8 shows the variation of carrier density with the temperature of elemental Ge. The layers obtained by checking the background are always n-type with a charge density of 2-4×10¹⁶ cm⁻³. The layers grown in Ge contaminated by previous deposition are also n-type with a charge density of either 2-4×10¹⁶ cm⁻³, if the temperature of the previous Ge doping source is lower than 650° C., or a charge density of at least one order of magnitude less than that of the external doping level in the previous deposition, if the temperature of Ge is higher than 650° C.

Unlike Zn doping, in which the doping almost linearly increases with the Zn temperature, Ge doping has its own characteristics. The Ge doping level remains almost constant, at 6-8×10¹⁶ cm⁻³, when the Ge temperature is lower than 650° C., and increases sharply, when the Ge temperature is higher than 650° C. This is one of the disadvantages of Ge doping, because it may make it difficult to control the doping levels by varying the Ge temperature.

It has been shown that Ge is transported as an oxide, and the transport reaction for Ge is:

Ge(s)+H₂O(g) [symbol] GeO(g)+H₂(g) (5)

The carrier density of the layers obtained from contamination-checking is always one order of magnitude less than that of externally doped ones. The maximum doping level we could reach in this way is 2-4×10¹⁸ cm⁻³. One key difference between Te and Ge (or Zn) is that Te is transported by sublimation, which does not require water as a transport agent.

Unlike other external doping elements, the layers obtained from Te doping suffer from very poor surface morphology. Conditions indicated before no longer govern the surface morphology of epitaxial layers, if Te is introduced as the external doping source.

Comments on the External Dopings:

One thing that should be emphasized here is that all of the n or p-type epilayers with the broad ranges of charge densities shown before were obtained with the same GaAs, i.e. SI-GaAs source and substrate, and all other growth parameters were kept constant, except that different external dopants were introduced into the reactor. We have also observed that there is no influence of external dopants on carrier densities of epilayers, if the temperature of the dopants (Zn, Ge) is lower than 400° C. (and 280° C. for Te), which is not displayed in the figures shown/discussed above.

Now, principally, the procedure of the multilayer growth with various n or p-type doping levels is simplified, in order to control the external doping source of Zn or Ge and its temperatures. Selection of Zn or Ge and Te determines the resulting type of epilayers, p- or n-type, respectively. The temperature of the external dopants determines the doping levels. Technically, the only modification of the SPE system is that two movable baskets of external doping sources, along with thermocouples to measure the dopant temperatures, have to be introduced (rather than one). The baskets can always park at the end of the reactor where the temperature is well below 300° C., while external doping sources are not in use. The remaining problem may be cross-contamination between n- and p-type dopants, which could affect the abruptness of the p-n junctions and increase the compensation ratio. This can be solved by a shutter or a very tight cap, which can be put on the basket, or removed mechanically to another part of the chamber, when it is not in use.

Oval Discussion:

Three kinds of overgrowth: oval defects, boat defects, and plateaus. They are all elongated in the [110] direction, but they do not have the same size. For layers about 5 μm thick, the origin of the oval defects in MOCVD is proposed to be gallium rich areas, or clustering of arsenic vacancies. Impurity adsorption is involved in the creation of the boat defects and plateaus. Other typical defects were also observed on layers grown by MOCVD on (100) GaAs, which include four sided pyramids. The origin of these defects has been attributed to Ga droplets formed by the decomposition of trimethyl gallium, when AsH₃ is deficient. Pyramids are not seen on layers grown by SPE.

Oval defects also exist in layers grown by MBE, but due to causes different from those in layers grown by MOCVD. In MBE, they are elongated along the [110] direction. Oval defects have been extensively studied in MBE. They can be divided into three categories: substrate related, particulate related, and gallium source related. Each category contains an oval defect with a specific morphology. The substrate related defects have been attributed to threading dislocations or surface contaminations Ga₂O₃, C, or neutral contaminants in distilled water. Particulates on the substrate also cause oval defects. In this case, a macroscopic central core usually reveals the origin of the defects. Ga-related oval defects are distinguished from the others by a ridge along their length. The ridge spans the entire length or broadens into a flat facet in the middle of the defect. They originate either from Ga spitting directly from the effusion cell onto the substrate or from Ga excess on the substrate, as a consequence of the reaction of Ga₂O₃ followed by the reverse reaction on the substrate.

Growth Parameter Variation:

a. Variation of Spacer Thickness:

We replaced the spacers of various thicknesses (from 0.5 to 3.4 mm). The 0.3 mm thick spacer is normally used. Although the growth rate of the layers was reduced by almost one order of magnitude upon increasing the source to substrate distance from 0.3 mm to 3.44 mm, the oval hillock density remained constant. Here, we could explain why the substrate temperatures were used as the reference to water injection temperatures. It is obvious that as the thickness of the spacer increases, the substrate temperature decreases, even though the source temperature is kept constant. When the spacer is thick enough, Tinj (referred to substrate) is so low, for example 440 C, that it is out of the region B of the Figure shown, even though the Tinj (referred to source) remains unchanged (550 C).

FIG. 9 shows the morphological results versus different growth parameters.

Table 2 below shows the results of morphology study, as well:

| | Tint (C.) | | Growth | |
|---|---|---|---|---|
| Spacer | To | Tint (C.) | rate | |
| (mm) | (to Sou)¹ | (to sub)² | (μm/min) | Morphology |
| 0.3 | 550 | 481 | 0.35 | Mirror-like OHD 10⁴ cm⁻² |
| 0.5 | 550 | 476 | 0.3 | Mirror-like OHD 10⁴ cm⁻² |
| 1.0 | 550 | 455 | 0.18 | Mirror-like OHD 10⁴ cm⁻² |
| 1.5 | 550 | 445 | 0.14 | Mirror-like OHD 10⁴ cm⁻² |
| 2.0 | 550 | 440 | 0.11 | Milky Surface |
| 2.0 | 600 | 501 | 0.11 | Mirror-like OHD 10⁴ cm⁻² |
| 3.5 | 616 | 500 | 0.053 | Mirror-like OHD 10⁴ cm⁻² |

Notes for table above:
¹Tint (C.) (to sou) - Water injection temperature refers to source temperature
²Tint (C.) (to sub) - Water injection temperature refers to substrate temperature

Effects of spacers and temperature references of water vapor injection on the surface morphology and oval hillock density, OHD, of GaAs epitaxial layers grown by SPE are also studied.

b. Variation of Tsou and Tsub, with ΔT=40° C.:

The growth temperature of Tsou and Tsub were changed in a way in which the substrate temperature, Tsub, varied from the lowest possible (600° C.) to grow a layer, to 830° C., while the temperature difference between source and substrate was approximately maintained at about 40° C. No layer can be deposited by this technique when the substrate temperature is below 600° C. We found that the growth temperatures have little influence on the oval defect density, when they are both higher than 700 C. Below that temperature, the defect density is not affected, either, but another type of oval defect with a faceted head becomes the most common one. As it has already been mentioned, this defect is also seen occasionally at higher substrate temperatures. When a thin layer (about 1000A) of GaAs is first grown at Tsub=760° C., before resuming the growth at Tsub=660° C., split oval defects do not show up. They are replaced by structureless defects, characteristics of the layers grown at higher temperature. It indicates that the oval defects have their origin near or at the substrate surface. There is a strong possibility that twining reported by others could result from the growth temperature. Indeed, in MOCVD and MBE, layers were grown at 630 and 600 C, respectively. These temperatures are close to Tsub=660° C., for which the defects mentioned above are obtained.

c. Variation of ΔT (Tsou-Tsub), with Tsou=800 C:

The substrate temperatures were varied from 740° C. to 800° C., while the source temperature was kept constant, 800° C. The growth rate decreases, as the substrate temperature approaches the source temperature, which is also predicted by the diffusion controlled mode. No dependence of the oval hillock density on ΔT was observed. Generally speaking, the slower the vertical growth rate, the bigger the size of the hillock is. In other words, the lateral growth rate can be controlled not only by the variation of water vapor pressure, but also by other growth parameters which could affect the vertical growth rate. This is very important when device fabrications involve the use of lateral growth. It gives extra flexibility. For example, very low water vapor pressure corresponding to higher lateral growth rate may, however, result in resistive epitaxial layers, while thicker spacers or smaller source substrate temperature differences have no such negative influences.

Substrate Variation:

We found that by use of misoriented GaAs substrates, we were able to reduce the surface defect density from 10⁴ to 2 or 5×10² per cm².

### CONCLUSION

In SPE, the arsenic pressure is fixed by the thermodynamic equilibrium of the transport reaction at the source and substrate temperature. It is therefore not possible to change the VIII ratio to decrease the oval defect density, as it is in the case of MOCVD, as both oval defects and plateaus are affected the same way in SPE. By using vicinal substrates, one may conclude that all oval hillocks result from the contamination of the substrate surface.

Preparation of the Starting Materials:

a. GaAs Sources and Substrates:

Table 3 below shows the various GaAs wafers purchased from different companies. For the optimization of the surface morphology of the layers and for external doping experiments, the source of GaAs wafers was always undoped semi-insulating (SI) GaAs. Although all GaAs wafers, including SI GaAs, could be used as substrates, SI-GaAs wafers (10¹⁸ cm⁻³) were most often used. The source and substrate (1-2 cm²) were degreased in boiling trichloroethylene, rinsed successively with boiling acetone, boiling propanol, and room temperature deionized water. The wafers were then etched in H₂O:H₂O₂:NH₄OH (150:1:6) at room temperature for 3 min. After being rinsed with deionized water and blown dry with nitrogen, the source and substrate were ready to be loaded into the reactor.

b. External Doping Sources:

Elements or alloys were used as external doping sources. They included both n-type dopants, Ge and Te, and p-type dopants, Zn, brass, Au and Sn. These external sources were degreased in the same way as the GaAs sources and substrates, but they were not etched. Traditionally, the GaAs source not only provided the material to grow GaAs epitaxial layers, but also acted as a doping source because the dopants in the GaAs source also incorporate into the growing layer during the epitaxial growth. An alternative to dope the layer is to use other dopants, rather than the ones in the GaAs source. This practice is labeled as external doping.

TABLE 3
GaAs wafers from various sources:
(All wafers were polished at least on one side)

| GaAs Wafers | Specifications | Suppliers |
|---|---|---|
| undoped SI—GaAs | | MAICOM |
| Si doped GaAs (100) | No-N_{A} = 1-3 × 10¹⁸ cm−³ | Laser Diode, |
| | | Inc |
| Si-doped GaAs | No-N_{A} = 1-4 × lO¹⁸ cm−³ | Laser Diode, |
| (2° off (100) toward (110) | | Inc |
| Si-doped GaAs (100) | No-N_{A} = 1-3 × lO¹⁸ cm−³ | Sumitomo |
| Te-doped GaAs (100) | No-N_{A} = 2-3 × lO¹⁸ cm−³ | Laser Diode, |
| | | Inc |
| Zn-doped GaAs (100) | NA-Nₒ = 2-3 × 10¹⁸ cm−³ | Sumitomo |

Note:
No is donor concentration, and N_{A} is acceptor concentration.

SPE system and Epitaxy Conditions:

a. SPE System:

The SPE system can be divided into two parts: (i) the gas supply and (ii) the reactor. The gas supply provides various combinations of gas sources to meet the needs at different growth stages. It mainly consists of stainless steel pipes, valves, and flow meters.

The reactor part is a growth chamber which consists of the fused silica reactor, a heating system, and an exhaust system. The reactor can be opened at one end. One of our reactors was 37 cm long and had a 6 cm diameter. The fused silica holder holds the high purity graphite blocks, the GaAs source, and substrate, and it is also used as the gas inlet through the hollow tube fixed in a stainless steel base in which the open end of the reactor tube is inserted. This setup, similar to the glass-metal joints used in high-vacuum technology, is leak-proof. DFP-2 Poco graphite was used for both heat susceptors.

Fused silica spacers (Accumet), 0.03 cm thick, were normally used. The heating system has two lamps and two temperature controllers. Key element in the exhaust system is the burner.

b. Epitaxy Conditions:

After being degreased and etched, the source and the substrate were loaded into the reactor and were separated by spacers. The degreased external doping sources were introduced into the reactor at this time, too, if needed. The closed reactor was successively purged with dry N₂ for 30 min and dry H₂ for 10 min. Then, it was baked at 200° C. under dry H₂ for 15 min in order to remove adsorbed water. This (15 min baking) is an important step.

One Embodiment/Example:

The usual growth temperatures for the source (Tsou) and substrate (Tsub) are 800 and 760° C., respectively. These temperatures are read from the thermocouples inserted in the graphite susceptors, heating the GaAs source and substrate. Temperature fluctuations of the heating system were minimized down to 1° C. by using the controllers. Tsou was first raised from 200 to 500° C. with a temperature ramp R of 2.30° C. s⁻¹, then from 500 to 800 DC with R=1.25° C. s⁻¹. Simultaneously, Tsub was first raised from 200 to 450° C. with R=1.92° C. s⁻¹, then from 450 to 760° C. with R=1.29° C. s⁻¹. It takes therefore 370 s to reach the stable growth temperatures.

Water vapor with a known pressure is injected into the reactor during the rise of the temperature to the growth temperatures. The exact injection temperature, Tinj, and water partial pressure, PH₂O, were also studied. Changes of PH₂O from 0.008 to 4.58 Ton are obtained, by mixing dry and wet H₂ (obtained by bubbling H₂ in H₂O, maintained at 0° C.). Higher water vapor pressures, PH₂O, >>4.58 torr, were obtained in a similar way, but bubbling H₂ in room temperature water. The total pressure in the reactor was kept constant at 1 atm and the flow of H₂ +H₂O was at 550 cm³ min⁻¹.

External Doping:

External doping sources, after they were decreased, were introduced into the reactor, by placing them in a fused silica basket, which was pendant from the fused silica holder. There was a thermocouple right above the basket to monitor its temperature, but not to control it. The temperature of the basket was determined by its position from the graphite susceptor.

In this way, the temperature increase of the doping sources during the growth, usually a 15 min period, was about 50-60° C. This temperature increase is due to the temperature gradient produced by existing heating sources, heated graphite susceptors, which have been used as the heating source for external doping sources. An accurate temperature control of the doping source during the growth could be obtained either by the introduction of another heating source, or by slowly pulling the basket away from the graphite blocks during the deposition.

Methods of Electrical Characterization:

For all types of GaAs epitaxial layers, ohmic contacts were made by using the alloy In-Ag (90% In), alloyed at 350° C. For lightly doped p-type GaAs (10¹⁶ cm⁻³), an alloying temperature up to 450° C. was used.

Fabrication of SPE Grown p-n Junctions:

To make p-n junctions, the simplest way is to grow one n type GaAs epitaxial layer on a p type GaAs substrate, and vice versa. Desired free carrier concentrations can easily be obtained by the external doping technique. After the deposition of a layer, a few mesas could be made on the epitaxial layer by a conventional photolithographic technique and wet etching. In our case, nail polish was used as a mask to protect certain areas on the epitaxial layer, and the unprotected area was etched with a mixture of H₂O:H₂SO₄:H₂O₂ (5:4:1). In order to have a good isolation, the etching should remove the unwanted epitaxial layer completely. Finally, ohmic contacts were made on the two sides of the junction.

### Another Embodiment:

Without opening the chamber, we are able to not only provide different dopants, but also grow different epi-material. One method is to use a disk of any shape, both for the source and substrate, with a motor behind it, to rotate the disk to different positions. Within that big circle or disk, there are a series of smaller disks. Embedded in those disks (or graphite heat susceptors, which are SiC coated to avoid contamination from graphite into the chamber, hence avoiding increase of background doping) are wafers of similar doping concentration or different dopants/concentration(s). The operation can be computer controlled or manual. So, the different dopants can be in the chamber, and the rotating or lateral moving disks or railings/vehicles/baskets can facilitate the selective deposition/relative rate of those dopings.

### Another Embodiment:

The source and/or substrate wafers benefit from vertical movements by lifts/robots/elevators and/or by circular movements, either individually or as group, through circular movements, lateral movements, perpendicular movements (up/down movements), and/or time truncated movements (X, Y, Z, T). Time truncated events allude to a computer controlled apparatus, where, depending on the growth details (such as transport agent pressures, time, thickness of growth layer, etc.), certain instructions are made to the processor to take certain movements which can be lateral, circular, perpendicular, etc., or any combination thereof.

In general, we can have an array of wafers, compartmentalization, to the tune of several thousand wafers, and multi-wafer chamber.

An Application for Solar Cells, using Polycrystalline Material:

We refer to the reference “Why CuInGaSe₂ and CdTe polycrystalline thin film solar cells are more efficient than corresponding single crystal,” by A. Boslo, N. Romeo, A. Podesta, S. Mazzamuto and V. Canevari, published in Cryst. Res. Technol. 40, No. 10-11, 1048-1053.

CuInSe₂ based materials is grown by means of columnar grains, with very special grain boundaries (GBs). Much of the thinking about GBs is based on their similarity to surface structures. Since various electronic measurements have demonstrated that the free surface of chalcopyrite CuGaInSe₂ exhibit a type inversion, it is possible to suppose that this behavior is also the same in the GBs. This means the existence of a barrier that prevents the motion of one type of carrier into the GBs/surface. To explain the origin of such barrier, we can suppose that the ordered defect compound formed on the chalcopyrite surface contains a high concentration of donors. The absence of holes inside the GB prevents GB electrons from combining Furthermore, the bulk material in polycrystalline material is purer than in single crystals, since impurities segregated to the GBs. This explains the superiority of polycrystalline CuInSe₂ solar cells over their crystalline counterpart.

It is also remarkable that the highest efficiency CdTe PV devices are fabricated from polycrystalline, rather than single crystal CdTe. This is probably due to the fact that the grain boundaries both in CdS and CdTe are passivated by the segregation in grain boundaries of insulating materials, like CdF₂, CdSO₃ and CdSO₄ in the CdS films, or CdTeO₃ in the CdTe films. In other words, probably, there exists an electron barrier at the grain boundaries that makes devices fabricated from II-VI compounds less sensitive to grain boundaries than solar cells made from III-V or group IV materials. Moreover, the heat treatment, in the presence of CdCl₂ of the CdS/CdTe system, is effective in the grain growth, and enhances the interdiffusion of sulfur and tellurium, forming the intermixed layer Cd(S,Te) at the interface. This is believed to shift the actual pn junction into the CdTe and to passivate the metallurgical heterointerface.

Controlling the intermixed layer between CdS and CdTe, both during the CSS deposition of the absorber layer, and during the CdCl₂ heat treatment, it is possible to maximize the photovoltage Voc and the fill factor (FF).

So, this method can be applied to both polycrystalline and monocrystalline III-V, in addition to other semiconductors, in addition to other methods: LPE, MOCVD, MBE, CBE, etc.

Note about Solar Cells:

Some of the key issues that affect the high efficiency multi junction solar cells are:

a. Contact loss Reduction

b. Surface/interface recombination loss reduction

c. Bulk recombination loss reduction

d. Lattice matching

e. High quality epilayer

f. Carrier confinement

g. Photon confinement

h. Current matching

i. Material selection

j. Device structure

k. Optical loss reduction (AR)

l. Cell interconnection loss reduction (Tunnel junction)

Another Embodiment for Solar Cells:

To make the multi junction cell, such that one can electrically access each cell by itself, i.e. top and bottom connections, with two additional connections for the buried top cell to middle cell connection, and the middle to bottom cell connection: We can serially connect each group of cell to an individual MPPT, and input that into the inverter. Then, spectral shifts will not result in the whole stack working at the capacity of the worst cell. (For description of MPPT, please refer to the following URL: http://www.blueskyenergyinc.com/pdf/Blue Sky What is MPPT .pdf.)

### Another Embodiment:

The cells that are used are 10.5×11.5 mm. Active collection area is 10×10 mm, and the optical surface is anti-reflective coated. On opposite sides of the top of the cell, there are two 0.050 inch wide and 10 mm long gold coated strips, which provide the negative termination. On the bottom of the cell, there is a 10.5×11.5 mm solid gold coated pad, for the positive termination and heat transfer.

Our users then mount the bare cell using H₂OE epoxy in the center of a 100×100×3 mm thick copper (primary heat sink) using a bond line of about 2-3 mils.

### Other Embodiments:

(These are just examples, and scope of coverage is broader.)

All of the above teachings can be applied to the following paragraphs:

It can be applied to any semiconductor (Si, II-IV, III-V, etc.) or metal/other material (e.g. plastic). It can be applied to other growth methods, such as MBE or MOCVD, or in combination of any of these methods. It can be applied to any devices, such as solar cell, FET, or HBT. The dopants or elements growth (for binary, ternary, and so on, with more elements/layers/structures) (for abrupt or ramping interfaces/dopings) can come from the same basket/source or multiple baskets, from circular tray, or trays, other shape trays, with different moving mechanism, such as rotation or lateral, or angular or vertical, by itself or with respect to other objects, or using the cover or cap to stop the flow of material, or any other valve or shutter, or ionization/magnetic techniques to block the flow, using different temperature controls, on one or more baskets or sources, on absolute or relative temperatures, or using different catalyst or ambient for reaction, to use physical or chemical reactions, to produce any dopant of any form and any bandgap engineering of any form, for any structure or material, for any application, or in combination to other growth methods, such as MBE, automatically by a computer, using a calibration curve, or manually by an operator, in situ or with interruptions, in combination with other manufacturing equipment, such as evaporator, so that there is an option not to open the chamber to do all of the above, if desired, for faster growth time.

One example: We can have one or more baskets, with one or more elements or compounds, together with one or more sources, combining, defusing, mixing, alloying, or integrating, in solid, liquid, or gas forms, into binary, ternary, or higher-order compounds, as a polycrystalline, single crystal, or amorphous materials. For example, for GaInAs, we have:

2GaP+H₂O [symbol] Ga₂O+H₂+P₂

Also, we have Indium in a basket, and based on prior calibration curves, we can adjust distances, angles, orientations, and temperatures, for relative or absolute values, to produce the right alloy, with the right mole fraction, and good crystallinity/surface morphology.

For example, we can introduce In by heating or combination of heating and carrier gas, such as combination of H₂O and H₂, or I₂, or ZnCl₂, or ZnCl₂ and H₂, or I₂ plus H₂, or PCl₃, or H₂ (ZnCl₂). ZnCl₂ can be used both as a transport agent and a doping agent.

In addition, for multiple growth, the substrate can rotate or move, with respect to other objects, to grow in series or parallel, or combination, or growth in one chamber having multiple substrates, or multiple chambers each having one or more substrates, for better control of uniformity, or with chambers being flat or in multiple floors stacked on top of each other, or using railing or rotations/disks, or grow the different layers in different chambers, to reduce cross contamination, chambers being in sequence, and also in parallel, or cleaning procedure, to clean up the system before next growth, to reduce cross contamination, or dedicate chambers for specific material or devices, to speed up the process, or to lift the cap or top surface of a mega-chamber with a lift or crane, or to have chambers within chambers, for quality control, and better reproducibility, to be able to grow fast by SPE, and grow many at one time, to reduce cost by many orders of magnitude, compared to competition, such as MBE method, and reduce cost and efficiency for devices, such as solar cells, but not limited to any specific device, material, application, process, or growth methods.

Other Examples:

The growth chamber can also be stationary.

The doping and elemental baskets have fixed or movable positions, with respect to substrate, or with respect to each other. Their temperatures are adjusted separately, or relatively, or in combination, to adjust quality, morphology, defects, crystallinity, growth rate, material composition, for example for ternary compound AlGaAs, doping efficiency, doping profile, structure/layer profile/engineering/design, abrupt or gradual modification of doping or grading layers, speed of growth, rate of cooling/heating material or substrate, based on calibration, or predefined property/requirement/design/device/material composition. Angle and speed of flow of ambient are also variable/adjustable, depending on the growth requirements and constraints.

### CONCLUSION/SUMMARY

Any variations of the teachings above are also meant to be protected by the current patent application.

The foregoing descriptions of specific embodiments of the present invention have been presented for purposes of illustration and description. They are not intended to be exhaustive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various embodiments with various modifications as are suited to the particular use contemplated. It is intended that the scope of the invention be defined by the Claims appended hereto and their equivalents.

What is claimed is:

1. A method for the growth of material, comprising:
separating a first source and a first substrate by one or more spacers;
heating the source and substrate in the presence of a first gas under conditions sufficient to transfer material from the source to the substrate; and
providing a second gas to the source and substrate qualitatively and/or quantitatively different from the first gas.

2. The method of claim 1, further comprising:
placing the separated first source and first substrate into a growth chamber; and
purging the growth chamber with the first gas prior to heating the substrate, wherein the source and substrate are heated in the growth chamber, and the second gas is provided in the growth chamber without opening the growth chamber between heating the source and substrate in the presence of the first gas and providing the second gas.

3. The method of claim 1, wherein the first gas comprises a first transport agent gas, and the second gas comprises a second transport agent gas.

4. The method of claim 3, further comprising purging the growth chamber with a gas other than the first transport agent gas, prior to purging the growth chamber with the first transport agent gas.

5. The method of claim 4, wherein the first transport agent gas consists essentially of CO₂, H₂O, I₂, ZnCl₂, PCl₃ and/or H₂ and the gas other than the first transport agent gas consists essentially of N₂.

6. The method of claim 2, further comprising introducing one or more first dopants into the growth chamber prior to purging the growth chamber with the first gas.

7. The method of claim 6, further comprising introducing one or more second dopants into the growth chamber.

8. The method of claim 6, wherein the one or more first dopants comprise a p-type dopant, an n-type dopant, and/or one or more members of the group consisting of Ge, Te, Zn, brass, Au, Sn, and Cu.

9. The method of claim 6, further comprising introducing one or more sources of the one or more first dopants into an external basket communicatively coupled to the growth chamber after placing the first source and first substrate into the growth chamber, but prior to purging the growth chamber with the first gas.

10. The method of claim 1, wherein said one or more spacers each have a thickness of about 0.3 mm to 3.4 mm

11. The method of claim 1, wherein said growth chamber comprises:
an intake element configured to receive the first and second gases from the supply chamber;
a holder configured to hold a source and substrate;
a reactor configured to enclose the holder, the reactor containing an opening for the intake element; and
a heating element configured to heat the source and/or substrate.

12. The method of claim 11, wherein said holder comprises a plurality of holders, each configured to hold a unique source and a unique substrate, wherein each unique source and unique substrate is capable of receiving a unique gas or combination of gases at unique rate(s).

13. The method of claim 12, wherein each of the plurality of holders can be moved vertically and/or horizontally independently of the other holders and/or in concert with the other holders.

14. The method of claim 12, wherein the reactor comprises a plurality of reactors each corresponding to a unique one of the plurality of holders.

15. The method of claim 11, wherein said reactor is configured to maintain each of the first and second gases at a pressure of greater than 1 torr to 1 atm.

16. The method of claim 11, wherein said heating element is configured to heat the source at a first temperature and the substrate at a second temperature different from the first temperature, the first temperature and the second temperature causing growth of a material from the source on the substrate by a transport reaction between the first gas and the source.

17. The method of claim 16, wherein the second temperature causes growth of the material from the source by a reverse reaction on the substrate of a product of the transport reaction.

18. The method of claim 1, wherein the first gas includes CO₂.

19. The method of claim 18, wherein the first gas further includes H₂.

20. The method of claim 19, wherein said second gas comprises at least one member of the group consisting of O₂, N₂, I₂, ZnCl₂, and PCl₃.
